(19) United States
(12) Patent Application Publication
(10) Pub. No.: US 2025/0320606 A1
(43) Pub. Date: Oct. 16, 2025

(54) LOW INDEX POROUS SILICON OXIDE AND SILICON NITRIDE CO-DEPOSITION METHOD

(71) Applicant: Thomas Robert Omstead, Newbury Park, CA (US)

(72) Inventor: Thomas Robert Omstead, Newbury Park, CA (US)

(21) Appl. No.: 18/821,197

(22) Filed: Aug. 30, 2024

Related U.S. Application Data
(60) Provisional application No. 63/629,979, filed on Apr. 10, 2024.

(51) Int. Cl. C23C 16/505; C23C 16/30; C23C 16/52; C23C 16/56; H01L 21/02

(52) U.S. Cl. CPC C23C 16/505; C23C 16/308; C23C 16/52; C23C 16/56; H01L 21/0214; H01L 21/02211; H01L 21/02274; H01L 21/0234

(57) ABSTRACT

A method for depositing low index silicon dielectrics involves co-depositing them with carbon to form a matrix, followed by removal of the carbon using an oxygen-containing plasma. The resulting silicon oxide, silicon nitride, or silicon oxynitride exhibits a porous structure with a high degree of porosity, exceeding 70 percent. This results in a silicon oxide index of refraction below 1.18 or a silicon nitride index below 1.3.

### CROSS REFERENCE TO RELATED APPLICATIONS

This U.S. Non-Provisional patent application claims the benefit of U.S. Provisional Patent Application No. 63/629,979, originally filed as Non-Provisional patent application Ser. No. 18/632,240, on Apr. 10, 2024, and converted on Jul. 12, 2024, to a Provisional patent application, titled “LOW INDEX POROUS SILICON OXIDE AND SILICON NITRIDE CO-DEPOSITION METHOD”, by inventor Thomas Robert Omstead, the contents of which are expressly incorporated herein by this reference as though set forth in their entirety and to which priority is claimed.

### FIELD OF USE

The present disclosure is generally directed to a method of depositing low index silicon dielectrics, and more specifically to a method of depositing low index silicon dielectrics with exceptional porosity, suitable for optical and semiconductor applications.

### BACKGROUND

In both optical and semiconductor realms, there's a burgeoning demand for low-index films, pivotal in applications such as optical waveguides, anti-reflective coatings, thermal insulation, and semiconductor interconnects. Fulfilling criteria like mechanical robustness, environmental stability, and processing ease often steers towards silicon-based dielectrics.

The semiconductor industry relentlessly pursues the integration of ICs, striving for enhanced performance and denser chip layouts. Technological strides result in shrinking device dimensions, leading to reduced gate delays but heightened RC delays. These delays have curbed device speed since the 0.25 μm technology node.

Efforts to address RC delay involve adopting materials with low resistivity and dielectric constants. Copper (Cu) and low-k materials now dominate back-end-of-line (BEOL) interconnects, supplanting traditional Aluminum/Non-Porous Silicon setups. Traditional Low dielectric constant films tend to be expensive, difficult to deposit, and in cases not thermally stable.

### SUMMARY

To minimize the limitations in the prior art and to minimize other limitations that will become apparent upon reading and understanding the present specification, the present disclosure discloses new and useful devices, systems, and methods related to depositing low index silicon dielectrics.

The following presents a simplified overview of the example embodiments in order to provide a basic understanding of some embodiments of the example embodiments. This overview is not an extensive overview of the example embodiments. It is intended to neither identify key or critical elements of the example embodiments nor delineate the scope of the appended claims. Its sole purpose is to present some concepts of the example embodiments in a simplified form as a prelude to the more detailed description that is presented herein below. It is to be understood that both the following general description and the following detailed description are exemplary and explanatory only and are not restrictive.

Various embodiments of the present disclosure may be directed to the co-deposition of silicon with carbon to form a matrix, achieved via chemical vapor deposition (CVD) or physical vapor deposition (PVD).

The objective of the present disclosure is to fabricate low-index silicon dielectrics with exceptional porosity, suitable for optical and semiconductor applications. The method of the present disclosure is the co-deposition of silicon with carbon to form a matrix, achieved via chemical vapor deposition (CVD) or physical vapor deposition (PVD). The treatment of the present disclosure is the selective removal of carbon using oxygen-containing plasma, leaving behind a porous structure within the silicon matrix, preferably resulting in a porous silicon oxide, silicon nitride, or silicon oxynitride film with over 70% porosity and exhibiting low refractive indices.

Optical Applications. The porous films derived from this innovative method emerge as quintessential solutions for various optical applications. Their exceptionally low refractive indices make them prime candidates for anti-reflective coatings, where minimizing unwanted reflections is crucial for enhancing optical clarity and efficiency. Moreover, their remarkable light-guiding properties make them indispensable for crafting low-loss waveguides, pivotal components in modern optical communication systems and photonic devices. By harnessing the benefits of these porous films, optical systems can achieve unparalleled performance, characterized by enhanced light transmission, reduced signal loss, low reflection, and superior optical fidelity.

Semiconductor Integration. In the realm of semiconductor technology, the integration of porous films presents a paradigm shift in device performance optimization. Their introduction leads to a notable reduction in capacitance within semiconductor components, thereby mitigating undesirable RC time constants and minimizing signal interference. By effectively managing capacitance, these porous films empower semiconductor devices to operate at higher speeds, exhibit improved signal integrity, and deliver enhanced overall performance. Consequently, semiconductor manufacturers can realize significant advancements in device miniaturization, speed, and efficiency, driving innovation and competitiveness in the semiconductor industry.

Thermal Management. Beyond optics and semiconductors, the utility of porous films extends into the realm of thermal management, offering a multitude of benefits in insulating applications. Leveraging their inherently low thermal conductivity compared to non-porous counterparts, these films emerge as ideal candidates for insulating materials across various domains. Whether applied in windows to regulate indoor temperature, utilized as heat shields in aerospace applications, or integrated into spacecraft for thermal protection, these porous films excel in mitigating heat transfer and maintaining thermal equilibrium. Their lightweight nature, coupled with superior insulating properties, renders them indispensable for enhancing energy efficiency, ensuring occupant comfort, and safeguarding critical components from thermal stress in harsh environments. Thus, porous films usher in a new era of thermal management solutions, redefining standards of performance, reliability, and sustainability across diverse industries and applications.

These, as well as other components, steps, features, objects, benefits, and advantages, will now become clear from a review of the following detailed description of illustrative embodiments, the accompanying drawings, and the claims.

### BRIEF DESCRIPTION OF THE DRAWINGS

The drawings are of illustrative embodiments. They do not illustrate all embodiments. Other embodiments may be used in addition or instead. Details which may be apparent or unnecessary may be omitted to save space or for more effective illustration. Some embodiments may be practiced with additional components or steps and/or without all of the components or steps, which are illustrated. When the same numeral appears in different drawings, it refers to the same or like components or steps.

FIG. 1 is an illustration of one embodiment of a carbon film deposition and method of the present disclosure.

FIG. 2 is an illustration of the same deposition/method as FIG. 1, further introducing a silane gas, or silane similar gas.

FIG. 3 is an illustration of one embodiment of a formation of a porous dielectric film by the exposure of a SiCₓO_{y}N_{z} film to an oxygen or nitrous oxide in a plasma.

FIG. 4 is a flow diagram of one embodiment of a method of carbon removal from a SiCₓO_{y}N_{z} film via an oxidation step.

FIG. 5 is an illustration of one embodiment of an ICP-CVD reactor.

FIG. 6 is an illustration of one embodiment of a deposited SiCₓO_{y} structure consisting of a silicon oxide matrix embedded in carbon.

FIG. 7 is an illustration of one embodiment of a series of layers, each with a refractive index.

FIG. 8 is an illustration of one embodiment of the porous silicon oxide film being used as a heat barrier.

### DETAILED DESCRIPTION OF THE ILLUSTRATIVE EMBODIMENTS

In the following detailed description of various embodiments of the present disclosure, numerous specific details are set forth in order to provide a thorough understanding of various aspects of one or more embodiments of the present disclosure. However, one or more embodiments of the present disclosure may be practiced without some or all of these specific details. In other instances, well-known methods, procedures, and/or components have not been described in detail so as not to unnecessarily obscure aspects of embodiments of the present disclosure.

While multiple embodiments are disclosed, still other embodiments of the devices, systems, and methods of the present disclosure will become apparent to those skilled in the art from the following detailed description, which shows and describes illustrative embodiments of the devices, systems, and methods of the present disclosure. As will be realized, the devices, systems, and methods of the present disclosure are capable of modifications in various obvious aspects, all without departing from the spirit and scope of the present disclosure. Accordingly, the screenshot figures, and the detailed descriptions thereof, are to be regarded as illustrative in nature and not restrictive. Also, the reference or non-reference to a particular embodiment of the devices, systems, and methods of the present disclosure shall not be interpreted to limit the scope of the present disclosure.

Before the present methods and systems are disclosed and described, it is to be understood that the methods and systems are not limited to specific methods, specific components, or to particular implementations. It is also to be understood that the terminology used herein is for the purpose of describing particular embodiments only and is not intended to be limiting.

As used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

“Optional” or “optionally” means that the subsequently described event or circumstance may or may not occur, and that the description includes instances where said event or circumstance occurs and instances where it does not.

Throughout the description and claims of this specification, the word “comprise” and variations of the word, such as “comprising” and “comprises,” means “including but not limited to,” and is not intended to exclude, for example, other components, integers or steps. “Exemplary” means “an example of” and is not intended to convey an indication of a preferred or ideal embodiment. “Such as” is not used in a restrictive sense, but for explanatory purposes.

Disclosed are components that may be used to perform the disclosed methods and systems. These and other components are disclosed herein, and it is understood that when combinations, subsets, interactions, groups, etc. of these components are disclosed that while specific reference of each various individual and collective combinations and permutation of these may not be explicitly disclosed, each is specifically contemplated and described herein, for all methods and systems. This applies to all embodiments of this application including, but not limited to, steps in disclosed methods. Thus, if there are a variety of additional steps that may be performed it is understood that each of these additional steps may be performed with any specific embodiment or combination of embodiments of the disclosed methods.

The present methods and systems may be understood more readily by reference to the following detailed description of preferred embodiments and the examples included therein and to the Figures and their previous and following description.

In the following description, certain terminology is used to describe certain features of one or more embodiments. For purposes of the specification, unless otherwise specified, the term “substantially” refers to the complete or nearly complete extent or degree of an action, characteristic, property, state, structure, item, or result. For example, in one embodiment, an object that is “substantially” located within a housing would mean that the object is either completely within a housing or nearly completely within a housing. The exact allowable degree of deviation from absolute completeness may in some cases depend on the specific context. However, generally speaking, the nearness of completion will be so as to have the same overall result as if absolute and total completion were obtained. The use of “substantially” is also equally applicable when used in a negative connotation to refer to the complete or near complete lack of an action, characteristic, property, state, structure, item, or result.

As used herein, the terms “approximately” and “about” generally refer to a deviance of within 5% of the indicated number or range of numbers. In one embodiment, the term “approximately” and “about”, may refer to a deviance of between 0.001-10% from the indicated number or range of numbers.

Various embodiments are now described with reference to the drawings. In the following description, for purposes of explanation, numerous specific details are set forth in order to provide a thorough understanding of one or more embodiments. It may be evident, however, that the various embodiments may be practiced without these specific details.

Those skilled in the art will recognize many modifications may be made to this configuration without departing from the scope of the disclosed embodiments.

This method presents a novel approach to crafting low-index porous silicon dielectrics, catering to the escalating need for materials with tailored optical and electrical properties. By co-depositing silicon with carbon and selectively removing carbon via plasma treatment, highly porous dielectric films are realized. These films hold promise in photonics, optoelectronics, and semiconductor technologies, enriching device functionality and performance.

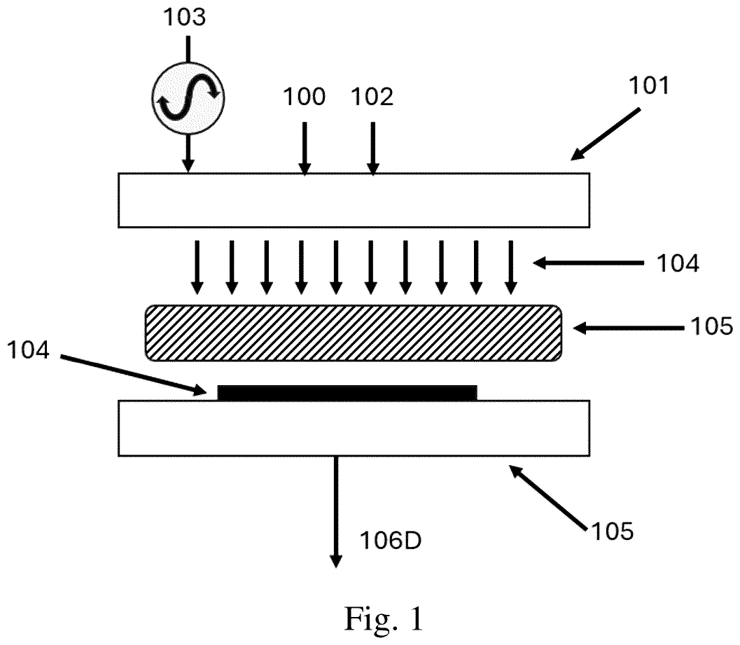

In order to deposit a low index porous film it is first necessary to establish the ability to grow a carbon film. There are many different methods to deposit this type of layer but the most economical is through the use of methane (CH₄) or a similar gas. The gas is introduced into a plasma typically with a carrier gas such as argon or helium as shown in FIG. 1. In the case of depositing a nitride or oxynitride film Nitrogen can also be introduced. Methane and carrier gas are introduced (100) into an rf powered showerhead (101). Gases are blended in the showerhead to form a uniform flow into the reactor (104). Methane is difficult to decompose (crack) and the addition of a small amount of oxygen can facilitate this (102). Radio Frequency (RF) energy (103) is introduced through the showerhead, which produces plasma (105) by coupling to a heated platen (106) at a temperature from room temperature to ˜400° C. at a low pressure of ˜100 mTorr. The heated platen can be electrically grounded, floating, DC Powered, or supplied with power, typically a low frequence (kHz) The plasma decomposes the methane (CH₄) to form a carbon film (C) which is typically a mixture of graphitic (SP₂) and diamond-like (SP₃) carbon (G). The carbon is formed by the reaction:

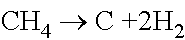

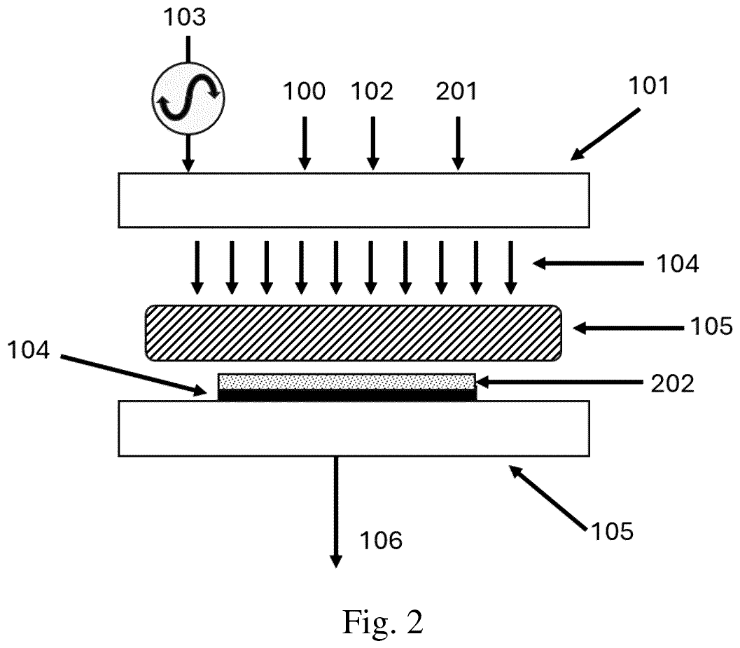

The deposition of the carbon film, in itself useful, is a key enabler for the formation of a porous dielectric film. In FIG. 2 we extend the deposition of carbon, as above, by the addition of silane or similar gas (201). Alternate porous material can also be deposited by using gases such as deuterated silane (SiD₄), Germane (GeH₄), Trimethyl Silane (or similar carbon-silicon precursor), Trimethylaluminum, (Al(CH₃)₃), Borazine, or other gases. The addition of Silane may include the addition of oxygen (O₂) or nitrous oxide (N₂O)₂ as an oxygen source or the addition of nitrogen (N₂) as a nitrogen source. It has been found that the addition of oxygen catalyzes the decomposition of methane. The combination of gases forms a film of SiCₓO_{y}N_{z} which is the basis of this invention. The flow Silane is typically very low ˜2 sccm in order to give the maximum porosity.

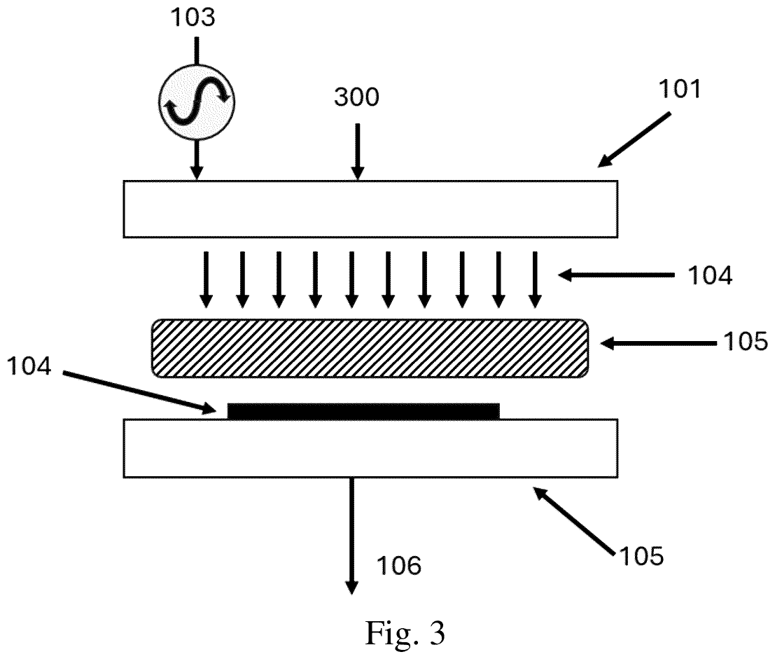

The porous dielectric film is formed (FIG. 3) by the exposure of the SiCₓO_{y}N_{z} film to an oxygen or nitrous oxide (300) into the plasma. In the most simple case the reaction that occurs is:

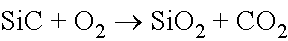

As the silicon oxide matrix is embedded in carbon the removal of the carbon results in a porous material as shown in FIG. 3. In the case of Silicon Nitride the reaction is:

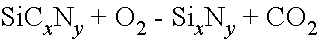

It is possible to make a Nitride or Oxynitride matrix by adjusting the gas mixture.

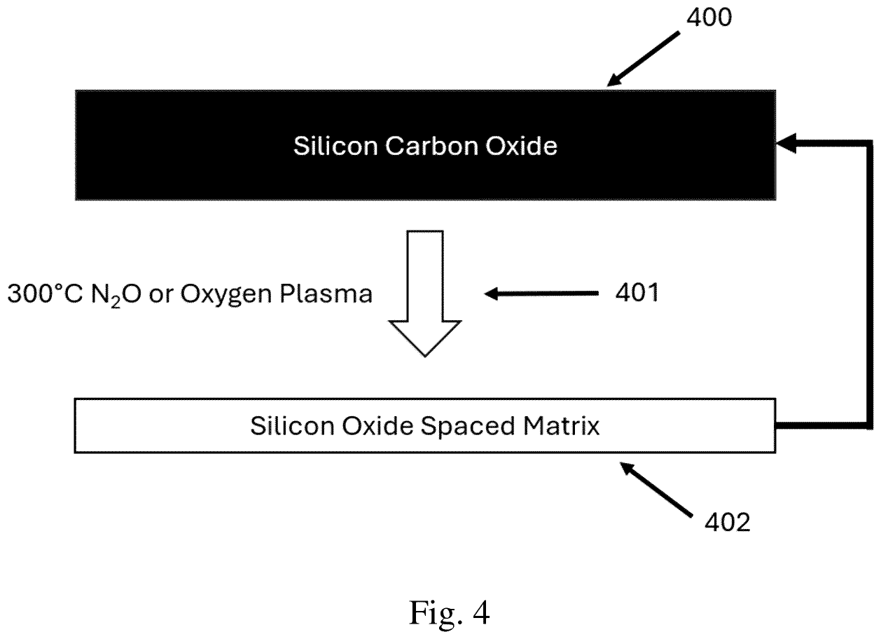

When eliminating Carbon from the Silicon Oxide matrix to form Porous Silicon Oxide the removal of carbon is limited by the diffusion of oxygen and Carbon Dioxide. In order to facilitate the removal of carbon a cycle can be made with a deposition of SiCₓO_{y}N_{z} followed by an oxidation step as shown in FIG. 4. The SiCₓO_{y} film (400), which typically has a refractive index of 2.3, a thickness of 2 μm, and a Dielectric Constant of 5.3. After exposure to the Oxygen containing plasma (401) the resulting material is a web-like porous material with a refractive index of 1.18, a thickness of 0.8 um, and a Dielectric Constant of 1.4.

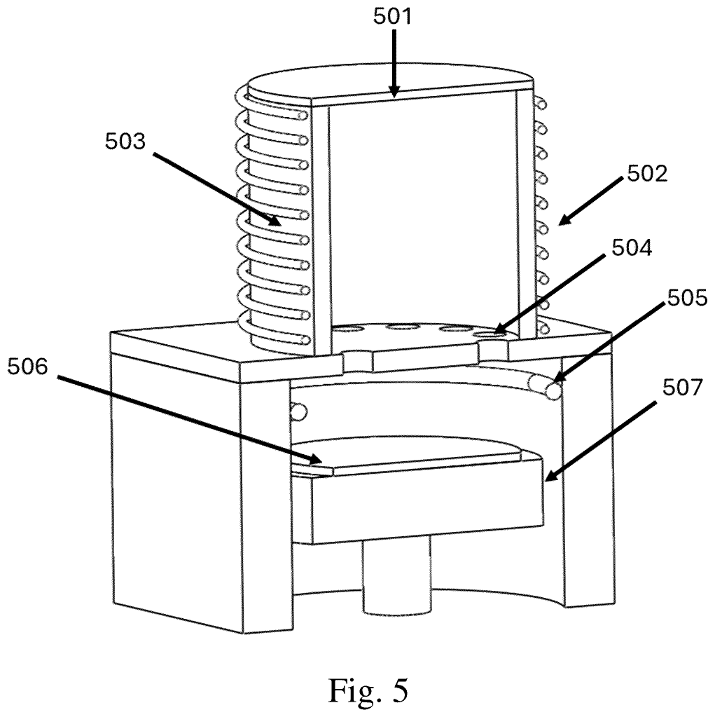

An alternate method of depositing the SiCₓN_{y} film is with a CVD reactor equipped with an ICP coil. In FIG. 5 we see the use of an ICP-CVD reactor for this process. Non-depositing gases, such as Oxygen, N₂O, and Helium are injected in the top of the reactor (501). An inductive coil, supplied with RF energy (502), which is isolated from the plasma by an insulating liner (503). In the coil area the formation of metastable Helium can transfer energy to decompose Oxygen and Nitrogen into radicals which enhance the decomposition other molecules and radicals:

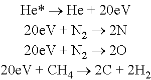

The decomposed molecules and radicals flow through a baffle plate (504), where it is mixed with gases such as CH₄ and SiH₄ through an injection coil (505), where they deposit on a substrate (506) that is sitting on a heated, RF energized, pedestal (507). It has been found empirically that increased flows of Helium though the coil can give an increased deposition rate, higher porosity, and a lower index of refraction. The ICP-CVD method has given a refraction of lower than 1.18 for SiO₂.

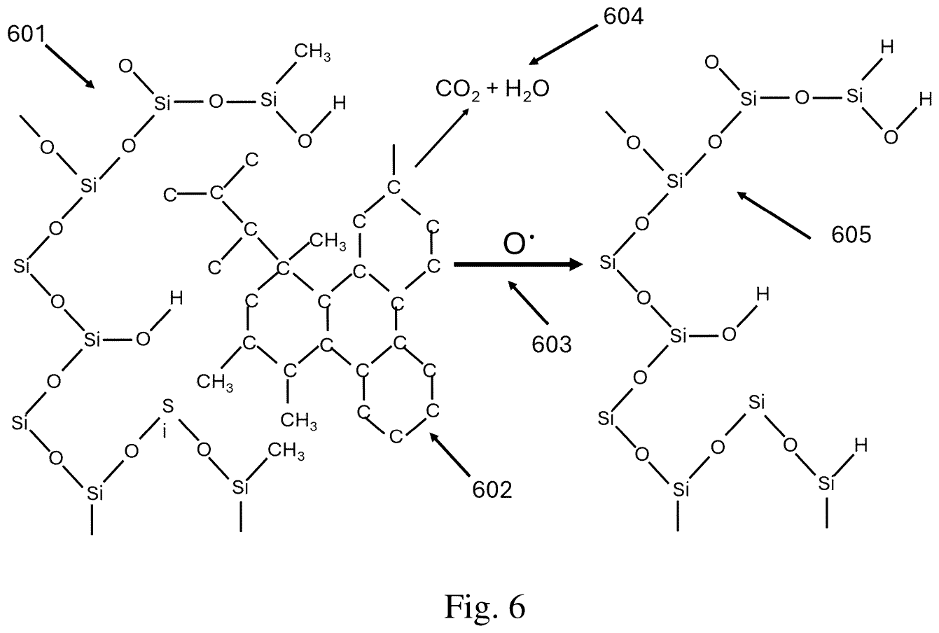

In order to better understand the process, we can see a representation of a deposited SiCₓO_{y} structure which consists of silicon oxide matrix embedded in carbon as shown in FIG. 6. The structure consists of a Silicon or Silicon Oxide structure (601) embedded in a Carbon structure (602). When exposed to an oxygen plasma (603), typically at 300° C., the carbon is removed forming Carbon Dioxide and Water (604) resulting in a Porous Silicon Oxide Structure (605). The size of the pores is typically very small and they cannot be readily observed by a Scanning Electron Microscope or similar techniques. The small size of the gaps in the porous film is an advantage for integrating the film in microelectronics, as the pore size should, in general be much smaller than the thickness of the film.

We see that the exposure of the SiCₓO film to the oxygen plasma makes it thinner, have a lower refractive index, a lower dielectric constant, lower optical absorption, and lower stress. Owing to their porous, web-like structure films of suitable porosity have nearly no stress. They can also expand and contract with their substrate and any subsequent films so that thermally induced expansion stress is eliminated or reduced.

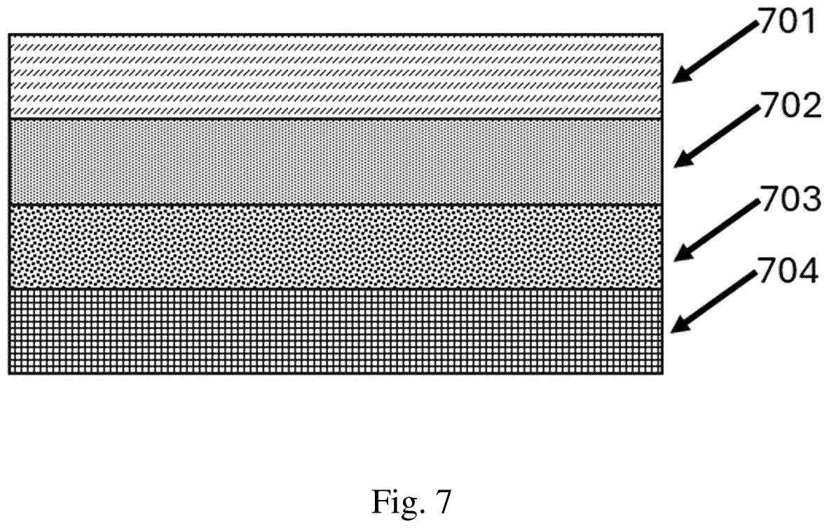

The manipulation of gas ratios, including Silane and Methane, alongside the modulation of plasma conditions, represents a versatile technique for precisely tailoring the index of refraction to meet specific requirements (Refer to FIG. 7). The index of each layer can be adjusted for example n=1.18 (701), n=1.25 (702), n=1.35 (703), and n=1.5 (704). By continually adjusting process conditions linear and non-linear index gradients are possible. Such gradients, finely tuned to the demands of various optical systems, offer a profound enhancement in performance across a spectrum of applications.

Furthermore, the strategic substitution of Silane with its deuterated counterpart, SiD₄ (Deuterated Silane), emerges as a pivotal innovation. This substitution strategically mitigates absorption at specific frequencies, thus bolstering the efficiency and effectiveness of waveguides. By deploying SiD₄, which exhibits altered isotopic characteristics, absorption phenomena within the waveguide structure are minimized, leading to improved signal propagation and fidelity.

These nuanced adjustments in gas composition, plasma conditions, and material substitutions transcend conventional limitations. They introduce a new capability wherein optical systems can be intricately engineered to meet the most demanding specifications, unlocking unprecedented performance thresholds and enabling breakthrough advancements in various technological domains.

The method's utilization of economical precursors, notably Silane, in the production of Porous Films signifies a significant advancement in cost-effective manufacturing processes. This approach not only renders the fabrication of thicker films, commonly employed for thermal insulation, feasible but also enhances their practicality and applicability in diverse settings.

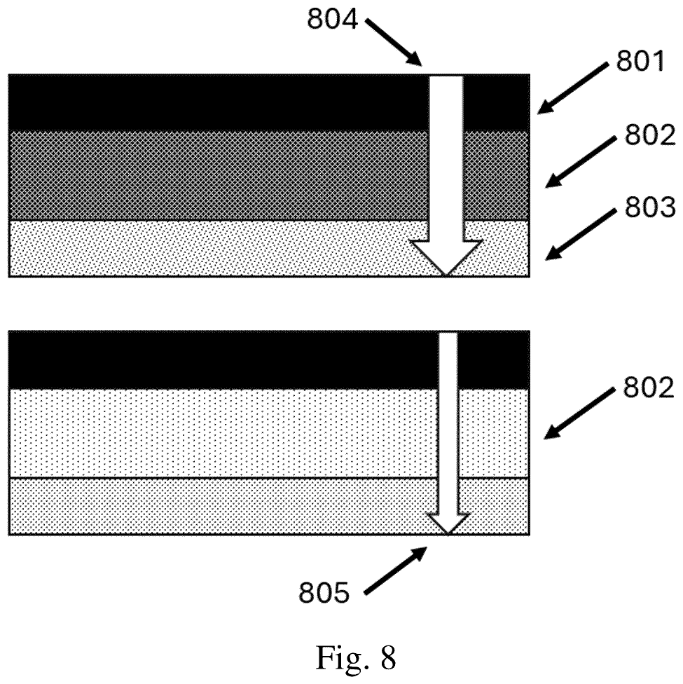

In FIG. 8, we see the use of this Porous Silicon Oxide film as a heat barrier. The transfer of heat from a hot surface (801) to a cold surface (803) is high (804) for the use of normal silicon oxide (802) as the heat transfer coefficient is 1.4 W/mK. In contrast the use of a porous Silicon Oxide (802) the heat transfer is much less (805) as the heat transfer coefficient is 0.5 W/mK. The substantial reduction in heat transfer coefficient observed in the porous variant underscores its superior insulative properties, making it an ideal choice for applications where thermal regulation and heat dissipation are paramount concerns.

Moreover, the inherent high thermal stability of inorganic films further underscores their superiority over polymeric or less stable materials. By virtue of their composition and structure, porous inorganic films excel in efficiently thermal conduction, offering enhanced thermal and stress management capabilities crucial for a myriad of industrial, commercial, and consumer applications. This superiority not only ensures optimal thermal insulation but also enhances the durability, reliability, and longevity of the materials, thereby fulfilling stringent performance requirements across various sectors.

In essence, the integration of low-cost precursors and the resultant production of Porous Films mark a significant leap forward in material science and engineering. This innovation not only addresses economic constraints but also delivers tangible benefits in terms of thermal efficiency, functionality, and performance, thereby catalyzing advancements in diverse fields ranging from construction and electronics to automotive and aerospace industries.

The SiCₓOy film can also be deposited by Physical Vapor Deposition from a Carbon/Silicon target or by co-sputtering Carbon and Silicon.

What is claimed is:

1. A process for creating a low-refractive index porous dielectric film comprising:
co-depositing a plurality of silicon, a plurality of carbon, a plurality of oxygen, and a plurality of nitrogen on a substrate; and
removing said plurality of carbon through a thermal annealing or an oxygen-rich plasma exposure, such that a low-refractive index porous dielectric film is created;
wherein said substrate comprises a chemical vapor deposition (CVD), a physical vapor deposition (PVD), or an inductively coupled plasma chemical vapor deposition (ICP-CVD).

2. The process of claim 1, wherein a plurality of methane gas is a carbon source, and a plurality of silane gas is a silicon source, wherein said carbon source and said silicon source allow co-deposition to form a SiCxOyNz matrix.

3. The process of claim 1, further comprising:
generating a plasma within a reaction chamber, within which said plurality of silicon, said plurality of carbon, said plurality of oxygen, and said plurality of nitrogen are placed, to decompose one or more introduced gases to form a SiCxOyNz matrix.

4. The process of claim 1, wherein a SiCxOyNz film is exposed to an oxygen-rich plasma, specifically chosen to selectively remove said plurality of carbon and create a porous structure with enhanced optical qualities.

5. The process of claim 4, further comprising:
optimizing a composition of said oxygen-rich plasma for effective removal of said plurality of carbon; and
wherein said oxygen-rich plasma is generated from a gas selected from the group of gases consisting of: an oxygen gas and a nitrous oxide gas.

6. The process of claim 2, further comprising:
adjusting a flow rate of said plurality of silane gas and said plurality of methane gas, along with a plasma operational parameter, to precisely control a porosity and a refractive index of said low-refractive index porous dielectric film, enabling customization of one or more film properties.

7. The process of claim 1,
wherein said low-refractive index porous dielectric film has a porosity exceeding 70 percent, a silicon oxide refractive index below 1.18, and a silicon nitride refractive index below 1.3.

8. The process of claim 1, incorporating a cyclic deposition and oxidation routine to enhance elimination of said plurality of carbon and to enhance a porosity of said low-refractive index porous dielectric film, thereby improving one or more structural characteristics of said low-refractive index porous dielectric film.

9. The process of claim 1, wherein said low-refractive index porous dielectric film is suitable for applications selected from the group of applications consisting of: optical waveguides, anti-reflective coatings, thermal insulation, sound insulation, and semiconductor interconnect isolation.

10. The process of claim 1, further comprising:
tailoring said low-refractive index porous dielectric film for enhanced thermal management applications by having a lower heat transfer coefficient and a lower thermal conductivity than traditional materials.

11. The process of claim 1, wherein said plurality of silicon comprises a deuterated silane (SiD4).

12. The process of claim 1, providing gases selected from the group of gases consisting of: Germane (GeH₄), Trimethyl Silane (SiH(CH₃)₃), Trimethylaluminum (Al(CH₃)₃), or Borazine (B₃H₆N₃) for depositing a variety of porous materials on said low-refractive index porous dielectric film.

13. The process of claim 1, wherein said low-refractive index porous dielectric film is optimized to modify one or more optical properties of said low-refractive index porous dielectric film, such that one or more linear and non-linear refractive index gradients are created within said low-refractive index porous dielectric film for advanced optical applications.

14. The process of claim 1, further comprising: employing an inductively coupled plasma (ICP)-CVD reactor and introducing helium gas through the ICP coil, which enhances gas decomposition and formation of a SiCxNy matrix for said low-refractive index porous dielectric films.

15. A porous silicon dielectric film produced by the process of claim 1, characterized by a heat transfer coefficient of 0.5 W/mK or lower, setting a new standard for thermal insulation properties in dielectric films.

16. The process of claim 15, optimized to minimize or eliminate internal stress, enhancing adhesion and mechanical stability when combined with other materials, and reducing thermal expansion mismatches for improved reliability and integration capability.

17. (canceled)
